(19) United States
(12) Patent Application Publication
(10) Pub. No.: US 2025/0099846 A1
(43) Pub. Date: Mar. 27, 2025

(54) APPARATUS AND METHOD FOR DETECTING ROTATIONAL STATE OF SMART RUBIK'S CUBE

(71) Applicant: GUANGZHOU TANZHI TECHNOLOGY CO., LTD, Guangzhou (CN)

(72) Inventor: Huimin WU, Guangzhou (CN)

(73) Assignee: GUANGZHOU TANZHI TECHNOLOGY CO., LTD, Guangzhou (CN)

(21) Appl. No.: 18/381,976

(22) Filed: Oct. 19, 2023

(30) Foreign Application Priority Data
Sep. 26, 2023 (CN) 202311253359.5

(51) Int. Cl. A63F 9/08; A63F 9/06; A63F 9/24

(52) U.S. Cl. CPC A63F 9/0842; A63F 9/0612; A63F 2009/2442

(57) ABSTRACT

The present application relates to the field of smart Rubik's cube technologies, and discloses an apparatus and a method for detecting a rotational state of a smart Rubik's cube. The apparatus includes a printed circuit board (PCB) assembly, a plurality of Hall sensors, and a central processing unit. The PCB assembly is disposed at a spherical core inside a Rubik's cube. The plurality of Hall sensors and the central processing unit are disposed at the PCB assembly. Positions of the plurality of Hall sensors correspond to Rubik's cube sides respectively. The central processing unit is connected to the plurality of Hall sensors. The present application implements non-contact detection of Rubik's cube state data, resolves a move-missing problem caused by physical wear and potential poor physical contact, and the detection precision is improved.

### TECHNICAL FIELD

The present application relates to the field of smart Rubik's cube technologies, and specifically to an apparatus and a method for detecting a rotational state of a smart Rubik's cube.

### BACKGROUND

At present, a conventional 3×3×3 Rubik's cube is a six-sided cube made of elastic hard plastic. The core is an axis, and the cube consists of 26 blocks. The 26 blocks include 6 fixed central blocks with one colored side, 8 rotatable corner blocks, and 12 rotatable edge blocks. When a side of the Rubik's cube is rotated, single colors of sides adjacent to the side are adjusted. After more rotations and changes of the Rubik's cube body with new patterns, each side consists of blocks of different colors. The gameplay is to restore the scrambled Rubik's cube body through rotations into six sides with single colors as soon as possible.

Nowadays sensors such as magnetic encoders and brush encoders are usually used to detect rotational angles of a Rubik's cube. However, magnetic encoders have high costs, high power consumption, and complex structure. Brush encoders have a short service life. Move missing tends to occur due to poor brush contact. As a result, an error occurs in the detection of rotational angles of the detected Rubik's cube, and detection precision is reduced.

### SUMMARY

In view of this, the present application provides a smart Rubik's cube and a method for detecting a rotational state of same, to resolve the problem that when sensors such as magnetic encoders and brush encoders are used to detect rotational angles of a Rubik's cube, an error occurs in the detection of rotational angles of the detected Rubik's cube, and detection precision is reduced.

According to a first aspect, the present application provides an apparatus for detecting a rotational state of a smart Rubik's cube, including: a printed circuit board (PCB) assembly, a plurality of Hall sensors, and a central processing unit, wherein the PCB assembly is disposed at a spherical core inside a Rubik's cube, the plurality of Hall sensors and the central processing unit are disposed at the PCB assembly, positions of the plurality of Hall sensors correspond to Rubik's cube sides respectively, and the central processing unit is connected to the plurality of Hall sensors, wherein
the Hall sensors are configured to: acquire output level signals, and transmit the output level signals to the central processing unit; and
the central processing unit is configured to: obtain an initial corner block arrangement array, an initial corner block direction array, an initial edge block arrangement array, and an initial edge block direction array, analyze the output level signals, update the initial corner block arrangement array, the initial corner block direction array, the initial edge block arrangement array, and the initial edge block direction array based on an analysis result, and generate Rubik's cube state data.

In the apparatus for detecting a rotational state of a smart Rubik's cube provided in the present application, the Hall sensors and the central processing unit are disposed at the spherical core inside Rubik's cube, to implement non-contact detection of Rubik's cube state data, resolve a move-missing problem caused by physical wear and potential poor physical contact, and implements precise detection of Rubik's cube state data through data interaction between the Hall sensors and the central processing unit, so that detection precision is improved.

In an implementation of the present application, the central processing unit is specifically configured to: when the output level signals are low level signals, determine a Rubik's cube rotational side and a Rubik's cube rotational direction based on Hall sensor identifiers, update the initial corner block arrangement array, the initial corner block direction array, the initial edge block arrangement array, and the initial edge block direction array based on the Rubik's cube rotational side and the Rubik's cube rotational direction, and generate the Rubik's cube state data based on an updated initial corner block arrangement array, initial corner block direction array, initial edge block arrangement array, and initial edge block direction array.

In the apparatus for detecting a rotational state of a smart Rubik's cube provided in the present application, the central processing unit determines the Rubik's cube rotational side and the Rubik's cube rotational direction based on Hall sensor identifiers, to improve the simulation precision of the Rubik's cube state data.

In an implementation of the present application, the PCB assembly includes a first PCB and a second PCB, and a support column is disposed between the first PCB and the second PCB; a group of Hall sensors are disposed at the center of a front surside of the first PCB; four groups of Hall sensors are disposed at the edge of a rear surside of the first PCB, and the four groups of Hall sensors are perpendicular to each other; a group of Hall sensors are disposed at the center of a rear surside of the second PCB; and each group of Hall sensors correspond to one Rubik's cube side.

In the apparatus for detecting a rotational state of a smart Rubik's cube provided in the present application, the first PCB and the second PCB are disposed in different layers, and the Hall sensors are respectively disposed at centers and edges of the first PCB and the second PCB, to implement corresponding detection of rotation of each side of the smart Rubik's cube. In addition, the apparatus for detecting a rotational state has simple structure, easy implementation, and low requirements in subsequent production and assembly.

In an implementation of the present application, each group of Hall sensors includes two Hall sensors, and the two Hall sensors rotate in two opposite directions respectively.

In the apparatus for detecting a rotational state of a smart Rubik's cube provided in the present application, two Hall sensors rotate in two opposite directions respectively to generate pulses, to facilitate recording of a rotation process of the smart Rubik's cube.

In an implementation of the present application, the Hall sensors are switch Hall sensors or linear Hall sensors.

In an implementation of the present application, the apparatus further includes a gyroscope sensor, wherein
the gyroscope sensor is disposed at the front surside of the first PCB, connected to the central processing unit, and configured to: acquire gyroscope acceleration data, and transmit the gyroscope acceleration data to the central processing unit.

In the apparatus for detecting a rotational state of a smart Rubik's cube provided in the present application, real-time detection of current positions of the sides of the smart Rubik's cube is implemented through the gyroscope acceleration data acquired by the gyroscope sensor, to further improve the simulation precision of the Rubik's cube state data.

In an implementation of the present application, the central processing unit is further configured to: receive the gyroscope acceleration data, convert the gyroscope acceleration data into an attitude angle, convert the attitude angle into quaternion data, and simulate the Rubik's cube state data based on the quaternion data.

In the apparatus for detecting a rotational state of a smart Rubik's cube provided in the present application, through processing of the gyroscope acceleration data, the Rubik's cube state data is simulated based on the quaternion data, to make the generated Rubik's cube state data more precise.

In an implementation of the present application, the central processing unit is further configured to: determine a Rubik's cube data packet based on the Rubik's cube state data, encrypt the Rubik's cube data packet, and send an encrypted Rubik's cube data packet to a user terminal within a preset time interval, and the user terminal displays the Rubik's cube state data based on the encrypted Rubik's cube data packet.

In the apparatus for detecting a rotational state of a smart Rubik's cube provided in the present application, the encrypted Rubik's cube data packet is sent to the user terminal within the preset time interval for display, to implement the accuracy and consistency of the Rubik's cube state data.

According to a second aspect, the present application provides a method for detecting a rotational state of a smart Rubik's cube, applied to the foregoing apparatus for detecting a rotational state of a smart Rubik's cube, wherein the method includes:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

In an implementation of the present application, the method further includes:
acquiring, by a gyroscope sensor, gyroscope acceleration data, and transmitting the gyroscope acceleration data to the central processing unit; and
receiving, by the central processing unit, the gyroscope acceleration data, converting the gyroscope acceleration data into an attitude angle, converting the attitude angle into quaternion data, and simulating the Rubik's cube state data based on the quaternion data.

### BRIEF DESCRIPTION OF THE DRAWINGS

To describe the technical solutions in specific embodiments of the present application or the prior art more clearly, the following briefly introduces the accompanying drawings required for describing the specific embodiments or the prior art. Apparently, the accompanying drawings in the following description show some embodiments of the present application, and a person of ordinary skill in the art may still derive other drawings from these accompanying drawings without creative efforts.

FIG. 1 is a structural block diagram of an apparatus for detecting a rotational state of a smart Rubik's cube according to an embodiment of the present application;

FIG. 2 is a schematic structural diagram of a front surside of a first PCB according to an embodiment of the present application;

FIG. 3 is a schematic structural diagram of a rear surside of a first PCB according to an embodiment of the present application;

FIG. 4 is a schematic structural diagram of a rear surside of a second PCB according to an embodiment of the present application; and

FIG. 5 is a schematic flowchart of a method for detecting a rotational state of a smart Rubik's cube according to an embodiment of the present application.

### DETAILED DESCRIPTION

In order to make the objectives, technical solutions and advantages of the embodiments of the present application clearer, the technical solutions in the embodiments of the present application will be clearly and completely described below in conjunction with the accompanying drawings in the embodiments of the present application. Obviously, the described embodiments are some of the embodiments of the present application, rather than all of the embodiments. All other embodiments obtained by persons skilled in the art based on the embodiments of the present disclosure without creative efforts fall within the protection scope of the present disclosure.

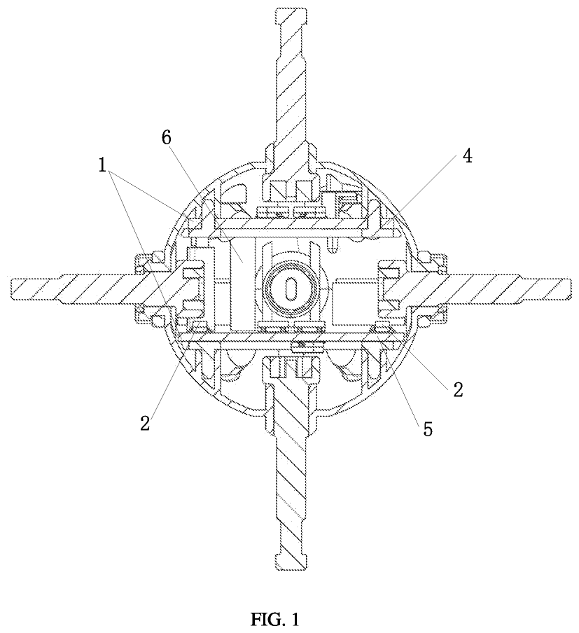

An embodiment of the present application provides an apparatus for detecting a rotational state of a smart Rubik's cube. As shown in FIG. 1, the apparatus includes a PCB assembly 1, a plurality of Hall sensors 2, and a central processing unit 3. The PCB assembly 1 is disposed at a spherical core inside a Rubik's cube. The plurality of Hall sensors 2 and the central processing unit 3 are disposed at the PCB assembly 1. Positions of the plurality of Hall sensors 2 correspond to Rubik's cube sides respectively. The central processing unit 3 is connected to the plurality of Hall sensors 2.

The Hall sensors 2 are configured to: acquire output level signals, and transmit the output level signals to the central processing unit 3.

The central processing unit 3 is configured to: obtain an initial corner block arrangement array, an initial corner block direction array, an initial edge block arrangement array, and an initial edge block direction array, analyze the output level signals, update the initial corner block arrangement array, the initial corner block direction array, the initial edge block arrangement array, and the initial edge block direction array based on an analysis result, and generate Rubik's cube state data.

Specifically, the central processing unit 3 is specifically configured to: when the output level signals are low level signals, determine a Rubik's cube rotational side and a Rubik's cube rotational direction based on Hall sensor identifiers, update the initial corner block arrangement array, the initial corner block direction array, the initial edge block arrangement array, and the initial edge block direction array based on the Rubik's cube rotational side and the Rubik's cube rotational direction, and generate the Rubik's cube state data based on an updated initial corner block arrangement array, initial corner block direction array, initial edge block arrangement array, and initial edge block direction array.

Further, the Rubik's cube has a total of 6 central blocks, 8 corner blocks, and 12 edge blocks. The central blocks are used for positioning the Rubik's cube rotational direction. Each corner block and edge block has a unique identifier. Four arrays (a corner block arrangement array, a corner block direction array, the edge block arrangement array, and the edge block direction array) are defined. In an initial state of the Rubik's cube, all corner blocks and edge blocks have initial values in the four arrays, that is, the initial corner block arrangement array, the initial corner block direction array, the initial edge block arrangement array, and the initial edge block direction array.

Further, after a side of the Rubik's cube is rotated, the central processing unit 3 obtains a Hall id of a corresponding side, determines, based on the Hall id, a side and a rotational direction corresponding to a central block, and determines which corner blocks and edge blocks are specifically rotated, to change values of the arrangement array and the direction array to generate latest state data of the Rubik's cube. Further, the decimal latest state data of the Rubik's cube is encapsulated into hexadecimal data, a packet header, a data length, a cyclic redundancy check (CRC) check value, a specific Rubik's cube state data packet are added, and advanced encryption standard (AES) encryption and distribution of the data are performed through a bluetooth protocol.

For example, the initial corner block arrangement array is (0, 1, 2, 3, 4, 5, 6, 7), the initial corner block direction array is (0, 0, 0, 0, 0, 0, 0, 0), the initial edge block arrangement array is (0, 1, 2, 3, 4, 5, 6, 7, 8, 9, 10, 11), and the initial edge block direction array is (0, 0, 0, 0, 0, 0, 0, 0, 0, 0, 0, 0). In this case, the white side of the Rubik's cube sides upward, and the green side sides the front. The white side at the top of the Rubik's cube is rotated anticlockwise. In this case, the central processing unit acquires a Hall sensor identifier, and determines, based on the Hall sensor identifier, that the Rubik's cube rotational side is the top white side, and the rotational direction is rotated anticlockwise to the right by 90 degrees. It is updated that the initial corner block arrangement array is (1, 2, 3, 0, 4, 5, 6, 7), the initial corner block direction array is (0, 0, 0, 0, 0, 0, 0, 0), the initial edge block arrangement array is (1, 2, 3, 0, 4, 5, 6, 7, 8, 9, 10, 11), and the initial edge block direction array is (0, 0, 0, 0, 0, 0, 0, 0, 0, 0, 0, 0). The updated arrays are used as the Rubik's cube state data.

In the apparatus for detecting a rotational state of a smart Rubik's cube provided in this embodiment, the Hall sensors and the central processing unit are disposed at the spherical core inside Rubik's cube, to implement non-contact detection of Rubik's cube state data, resolve a move-missing problem caused by physical wear and potential poor physical contact, and implements precise detection of Rubik's cube state data through data interaction between the Hall sensors and the central processing unit, so that detection precision is improved.

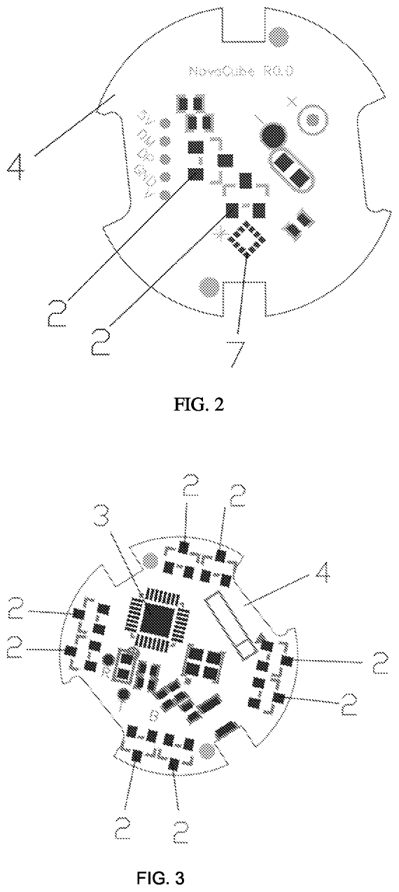

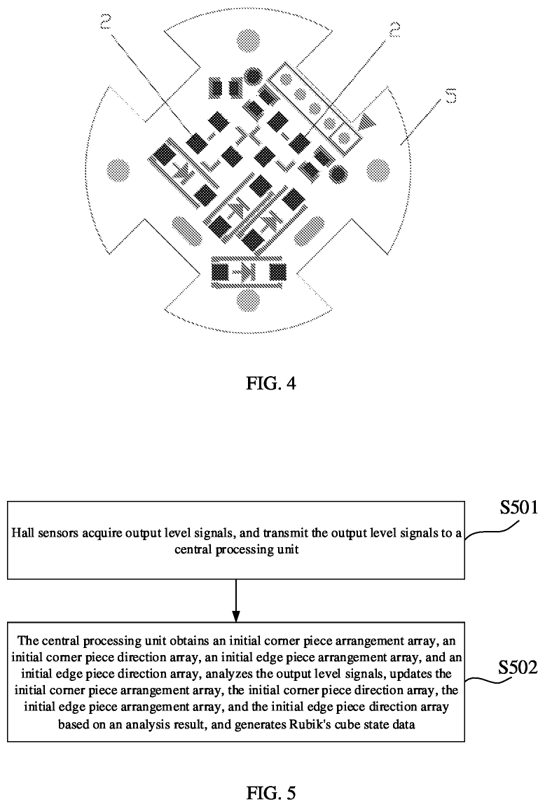

In some implementations of the present application, the PCB assembly 1 includes a first PCB 4 and a second PCB 5, and a support column 6 is disposed between the first PCB 4 and the second PCB 5. As shown in FIG. 2, a group of Hall sensors 2 are disposed at the center of a front surside of the first PCB 4. As shown in FIG. 3, four groups of Hall sensors 2 are disposed at the edge of a rear surside of the first PCB 4, and the four groups of Hall sensors 2 are perpendicular to each other. As shown in FIG. 4, a group of Hall sensors 2 are disposed at the center of a rear surside of the second PCB 5; and each group of Hall sensors 2 correspond to one Rubik's cube side.

Specifically, each group of Hall sensors 2 includes two Hall sensors 2, and the two Hall sensors 2 rotate in two opposite directions respectively.

Further, the first PCB 4 and the second PCB 5 are circular circuit boards. There are a total of 12 Hall sensors 2. The Hall sensor identifiers are numbered 1 to 12. The smart Rubik's cube has six sides. Each side corresponds to two Hall sensors 2. The two Hall sensors 2 rotate corresponding to two opposite directions.

Further, the Hall sensors 2 use switch Hall sensors or linear Hall sensors. The switch Hall sensors include micropower consumption Hall effect switches. An operating current of a single switch Hall sensor is lower than 5 uA, and a total operating current of 12 switch Hall sensors is approximately 60 uA. In this way, while the rotational state of the Rubik's cube is detected, the power consumption of the detection is reduced, and the switch Hall sensors have advantages of a long detection service life and high reliability.

Further, two Hall sensors 2 are arranged at the center of the front surside of the first PCB 4. The two Hall sensors 2 are orthogonally disposed. Dipole magnets corresponding to the two Hall sensors 2 rotate to induce orthogonal AB pulses, which may be used for recording a rotation move quantity and a rotate direction of the Rubik's cube top side. The central processing unit 3 counts the rotation move quantity, and determine an angle state of the side in combination with an initial position.

Further, two Hall sensors 2 are arranged at an interval of 90 degrees on the rear surside of the first PCB 4 along the edge of the circular circuit board. Dipole magnets corresponding to the two Hall sensors 2 rotate to induce orthogonal AB pulses, which are used for detecting angles of four Rubik's cube side sides perpendicular to the Rubik's cube top side.

Further, two Hall sensors 2 are arranged at the center of the rear surside of the second PCB 5 to detect an angle state of the Rubik's cube bottom side. A detection method is the same as the foregoing detection method for the Rubik's cube top side and the Rubik's cube side sides.

Further, the white central block side of the Rubik's cube corresponds to Hall sensor ids (that is, Hall sensor identifiers) of 1 and 2, the red central block side of the Rubik's cube corresponds to Hall sensor ids of 3 and 4, the red central block side of the Rubik's cube corresponds to Hall sensor ids of 5 and 6, the yellow central block side of the Rubik's cube corresponds to Hall sensor ids of 7 and 8, the orange central block side of the Rubik's cube corresponds to Hall sensor ids of 9 and 10, and the green central block side of the Rubik's cube corresponds to Hall sensor ids of 11 and 12. A Hall id being an odd number represents an anticlockwise rotation, and being an even number represents a clockwise rotation. Each pin is connected to an output pin of a Hall sensor 2. If the white central block side of the Rubik's cube is rotated clockwise, a pin of a general-purpose input/output (GPIO) corresponding to the Hall sensor id of 2 generates an interruption signal. Level signals of 12 GPIO pins are read from an interruption service function, the Hall sensor with the id of 2 is determined based on a pin correspond to a low level signal, and a Rubik's cube rotational side and a Rubik's cube rotational direction acquired by the corresponding Hall sensor 2 are obtained based on the Hall sensor identifier.

In the apparatus for detecting a rotational state of a smart Rubik's cube provided in this embodiment, the first PCB and the second PCB are disposed in different layers, and the Hall sensors are respectively disposed at centers and edges of the first PCB and the second PCB, to implement corresponding detection of rotation of each side of the smart Rubik's cube. In addition, the apparatus for detecting a rotational state has simple structure, easy implementation, and low requirements in subsequent production and assembly.

In some implementations of the present application, the apparatus further includes a gyroscope sensor 7.

The gyroscope sensor 7 is disposed at the front surside of the first PCB 4, connected to the central processing unit 3, and configured to: acquire gyroscope acceleration data, and transmit the gyroscope acceleration data to the central processing unit 3.

Specifically, a device driver program of a gyroscope is written. An x axis, a y axis, and a z axis of the gyroscope are set according to the driver program. The central processing unit 3 reads gyroscope acceleration data, that is, x-axis acceleration data, y-axis acceleration data, and z-axis acceleration data.

In the apparatus for detecting a rotational state of a smart Rubik's cube provided in this embodiment, real-time detection of current positions of the sides of the smart Rubik's cube is implemented through the gyroscope acceleration data acquired by the gyroscope sensor, to further improve the simulation precision of the Rubik's cube state data.

In some implementations of the present application, the central processing unit 3 is further configured to: receive the gyroscope acceleration data, convert the gyroscope acceleration data into an attitude angle, convert the attitude angle into quaternion data, and simulate the Rubik's cube state data based on the quaternion data.

Specifically, the gyroscope acceleration data is converted into an attitude angle (θ, ϕ, ψ), and a calculation formula is shown as follows:

$$θ = a tan 2 ( - ax , sprt ( ay * az + az * az ) ) , \qquad ( 1 )$$

$$ϕ = a tan 2 ( ay , az ) , \qquad ( 2 )$$

$$and$$

$$ψ = a tan 2 ( mz * sin ( ϕ ) - my * cos ( ϕ ) , mx * cos ( θ ) + my * sin ( θ ) * sin ( ϕ ) + mz * sin ( θ ) * cos ( ϕ ) ) . \qquad ( 3 )$$

In the foregoing formula, θ represents a pitch angle. ϕ represents a roll angle. ψ represents a yaw angle. ax, ay, and az respectively represent gyroscope acceleration data in an x-axis direction, a y-axis direction, and a z-axis direction, a tan 2 represents an arc tangent value, and mx, my, and mz respectively represent magnetic field strengths of the gyroscope in the x-axis [symbol] of the *cos(ϕ/2)−sin(ψ/2)*cos(θ/2)*sin(ϕ/2)+k*(cos(ψ/2)*cos(θ/2)*sin(ϕ/2)+sin(ψ/2)*sin(θ/2)*cos(ϕ/2) (4).

In the foregoing formula, i, j, and k respectively represent unit vectors on the x axis, the y axis, and the z axis that are perpendicular to each other.

Further, the Rubik's cube state data is simulated and presented by using the quaternion data q.

In the apparatus for detecting a rotational state of a smart Rubik's cube provided in this embodiment, through processing of the gyroscope acceleration data, the Rubik's cube state data is simulated based on the quaternion data, to make the generated Rubik's cube state data more precise.

In some implementations of the present application, the central processing unit 3 is further configured to: determine a Rubik's cube data packet based on the Rubik's cube state data, encrypt the Rubik's cube data packet, and send an encrypted Rubik's cube data packet to a user terminal within a preset time interval, and the user terminal displays the Rubik's cube state data based on the encrypted Rubik's cube data packet.

Specifically, the central processing unit 3 transmits the encrypted Rubik's cube data packet to the user terminal by using a bluetooth protocol.

Further, to avoid that a state of the Rubik's cube is not synchronous with a Rubik's cube state in the user terminal in a case that a network is unstable, the central processing unit 3 needs to record previous Rubik's cube state data, and send the previous Rubik's cube state data synchronously to the user terminal by using the bluetooth protocol. The user terminal perform state data comparison on the currently simulated Rubik's cube state data and stored Rubik's cube state data (for example, Rubik's cube rotational data of 9 previous times). If a result of the state data comparison shows a large difference, the user terminal presents latest Rubik's cube state data through a 3d figure.

Further, the central processing unit 3 periodically sends final Rubik's cube state data within the preset time interval (for example, 30 seconds). If the result of the state data comparison shows a large difference, the user terminal displays the latest Rubik's cube state data received within the preset time interval, to ensure the accuracy and consistency of the Rubik's cube state data.

Further, the user terminal may display the Rubik's cube state data by using flyCube (a smart Rubik's cube practice and battle platform, supporting 3D presentation of a Rubik's cube) software.

In the apparatus for detecting a rotational state of a smart Rubik's cube provided in this embodiment, the encrypted Rubik's cube data packet is sent to the user terminal within the preset time interval for display, to implement the accuracy and consistency of the Rubik's cube state data.

An embodiment of the present application further provides a method for detecting a rotational state of a smart Rubik's cube. As shown in FIG. 5, the method includes the following steps.

Step S501: Hall sensors acquire output level signals, and transmit the output level signals to a central processing unit.

Step S502: The central processing unit obtains an initial corner block arrangement array, an initial corner block direction array, an initial edge block arrangement array, and an initial edge block direction array, analyzes the output level signals, updates the initial corner block arrangement array, the initial corner block direction array, the initial edge block arrangement array, and the initial edge block direction array based on an analysis result, and generates Rubik's cube state data.

In some implementations of the present application, the method further includes:
acquiring, by a gyroscope sensor, gyroscope acceleration data, and transmitting the gyroscope acceleration data to the central processing unit; and
receiving, by the central processing unit, the gyroscope acceleration data, converting the gyroscope acceleration data into an attitude angle, converting the attitude angle into quaternion data, and simulating the Rubik's cube state data based on the quaternion data.

The method for detecting a rotational state of a smart Rubik's cube in this embodiment is applied to the apparatus for detecting a rotational state of a smart Rubik's cube in the embodiment shown in FIG. 1. Therefore, for specific implementation of step S501 and step S502, refer to corresponding description in the foregoing embodiment part shown in FIG. 1. Details are not described herein again.

It may be understood that the functions and beneficial effect of the method in this embodiment correspond to the functions and beneficial effect of the apparatus for detecting a rotational state of a smart Rubik's cube in the embodiment shown in FIG. 1. Details are not described herein again.

A person of ordinary skill in the art may be aware that, in combination with the examples described in embodiments disclosed in this specification, units and algorithm steps may be implemented by electronic hardware or a combination of computer software and electronic hardware. Whether the functions are performed by hardware or software depends on particular applications and design constraints of the technical solutions. A person skilled in the art may use different methods to implement the described functions for each particular application, but it should not be considered that the implementation goes beyond the scope of embodiments of this application.

It may be clearly understood by a person skilled in the art that, for the purpose of convenient and brief description, for a detailed working process of the foregoing system, apparatus, and unit, refer to a corresponding process in the foregoing method embodiments. Details are not described herein again.

In the several embodiments provided in the embodiments of this application, it should be understood that the disclosed system, apparatus, and method may be implemented in other forms. For example, the described apparatus embodiments are merely examples. For example, the division into the units is merely logical function division and may be other division during actual implementation. For example, a plurality of units or components may be combined or integrated into another system, or some features may be ignored or not performed. In addition, the displayed or discussed mutual couplings or direct couplings or communication connections may be implemented by using some intersides. The indirect couplings or communication connections between the apparatuses or units may be implemented in electronic, mechanical, or another form.

The units described as separate parts may or may not be physically separate, and parts shown as units may or may not be physical units, may be located in one place, or may be distributed on a plurality of network units. Some or all of the units may be selected depending on actual requirements to achieve the objectives of the solutions in embodiments.

In addition, functional units in embodiments of this application may be integrated into one processing unit, or each of the units may exist alone physically, or two or more units are integrated into one unit.

When the functions are implemented in the form of a software functional unit and sold or used as an independent product, the functions may be stored in a computer-readable storage medium. Based on such an understanding, the technical solutions in the embodiments of this application essentially, or the part contributing to the prior art, or some of the technical solutions may be implemented in a form of a software product. The computer software product is stored in a storage medium and includes several instructions for instructing a computer device (which may be a personal computer, a server, a network device, or the like) to perform all or some of the steps of the methods described in embodiments of this application. The foregoing storage medium includes: any medium that can store program code, such as a USB flash drive, a removable hard disk, a read-only memory (ROM), a random access memory (RAM), a magnetic disk, or an optical disc.

Although the embodiments of the present application are described in conjunction with the accompanying drawings, various modifications and variations may be made by those skilled in the art without departing from the spirit and scope of the present application, and such modifications and variations fall within the scope defined by the appended claims.

1. An apparatus for detecting a rotational state of a smart Rubik's cube, comprising: a printed circuit board (PCB) assembly, a plurality of Hall sensors, and a central processing unit, wherein the PCB assembly is disposed at a spherical core inside a Rubik's cube, the plurality of Hall sensors and the central processing unit are disposed at the PCB assembly, positions of the plurality of Hall sensors correspond to Rubik's cube sides respectively, and the central processing unit is connected to the plurality of Hall sensors, wherein
the Hall sensors are configured to: acquire output level signals, and transmit the output level signals to the central processing unit; and
the central processing unit is configured to: obtain an initial corner block arrangement array, an initial corner block direction array, an initial edge block arrangement array, and an initial edge block direction array, analyze the output level signals, update the initial corner block arrangement array, the initial corner block direction array, the initial edge block arrangement array, and the initial edge block direction array based on an analysis result, and generate Rubik's cube state data.

2. The apparatus according to claim 1, wherein the central processing unit is specifically configured to: when the output level signals are low level signals, determine a Rubik's cube rotational side and a Rubik's cube rotational direction based on Hall sensor identifiers, update the initial corner block arrangement array, the initial corner block direction array, the initial edge block arrangement array, and the initial edge block direction array based on the Rubik's cube rotational side and the Rubik's cube rotational direction, and generate the Rubik's cube state data based on an updated initial corner block arrangement array, initial corner block direction array, initial edge block arrangement array, and initial edge block direction array.

3. The apparatus according to claim 1, wherein the PCB assembly comprises a first PCB and a second PCB, and a support column is disposed between the first PCB and the second PCB; a group of Hall sensors are disposed at the center of a front surside of the first PCB; four groups of Hall sensors are disposed at the edge of a rear surside of the first PCB, and the four groups of Hall sensors are perpendicular to each other; a group of Hall sensors are disposed at the center of a rear surside of the second PCB; and each group of Hall sensors correspond to one Rubik's cube side.

4. The apparatus according to claim 3, wherein each group of Hall sensors comprises two Hall sensors, and the two Hall sensors rotate in two opposite directions respectively.

5. The apparatus according to claim 1, wherein the Hall sensors are switch Hall sensors or linear Hall sensors.

6. The apparatus according to claim 3, further comprising a gyroscope sensor, wherein
the gyroscope sensor is disposed at the front surside of the first PCB, connected to the central processing unit, and configured to: acquire gyroscope acceleration data, and transmit the gyroscope acceleration data to the central processing unit.

7. The apparatus according to claim 6, wherein the central processing unit is further configured to: receive the gyroscope acceleration data, convert the gyroscope acceleration data into an attitude angle, convert the attitude angle into quaternion data, and simulate the Rubik's cube state data based on the quaternion data.

8. The apparatus according to claim 1, wherein the central processing unit is further configured to: determine a Rubik's cube data packet based on the Rubik's cube state data, encrypt the Rubik's cube data packet, and send an encrypted Rubik's cube data packet to a user terminal within a preset time interval, and the user terminal displays the Rubik's cube state data based on the encrypted Rubik's cube data packet.

9. A method for detecting a rotational state of a smart Rubik's cube, applied to the apparatus for detecting a rotational state of a smart Rubik's cube according to claim 1, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

10. The method according to claim 9, further comprising:
acquiring, by a gyroscope sensor, gyroscope acceleration data, and transmitting the gyroscope acceleration data to the central processing unit; and
receiving, by the central processing unit, the gyroscope acceleration data, converting the gyroscope acceleration data into an attitude angle, converting the attitude angle into quaternion data, and simulating the Rubik's cube state data based on the quaternion data.

11. The apparatus according to claim 2, wherein the central processing unit is further configured to: determine a Rubik's cube data packet based on the Rubik's cube state data, encrypt the Rubik's cube data packet, and send an encrypted Rubik's cube data packet to a user terminal within a preset time interval, and the user terminal displays the Rubik's cube state data based on the encrypted Rubik's cube data packet.

12. The apparatus according to claim 6, wherein the central processing unit is further configured to: determine a Rubik's cube data packet based on the Rubik's cube state data, encrypt the Rubik's cube data packet, and send an encrypted Rubik's cube data packet to a user terminal within a preset time interval, and the user terminal displays the Rubik's cube state data based on the encrypted Rubik's cube data packet.

13. A method for detecting a rotational state of a smart Rubik's cube, applied to the apparatus for detecting a rotational state of a smart Rubik's cube according to claim 2, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

14. A method for detecting a rotational state of a smart Rubik's cube, applied to the apparatus for detecting a rotational state of a smart Rubik's cube according to claim 3, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

15. A method for detecting a rotational state of a smart Rubik's cube, applied to the apparatus for detecting a rotational state of a smart Rubik's cube according to claim 4, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

16. A method for detecting a rotational state of a smart Rubik's cube, applied to the apparatus for detecting a rotational state of a smart Rubik's cube according to claim 5, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

17. A method for detecting a rotational state of a smart Rubik's cube, applied to the apparatus for detecting a rotational state of a smart Rubik's cube according to claim 6, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

18. A method for detecting a rotational state of a smart Rubik's cube, applied to the apparatus for detecting a rotational state of a smart Rubik's cube according to claim 7, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.

19. A method for detecting a rotational state of a smart Rubik's cube, applied to the apparatus for detecting a rotational state of a smart Rubik's cube according to claim 8, wherein the method comprises:
acquiring, by Hall sensors, output level signals, and transmitting the output level signals to a central processing unit; and
obtaining, by the central processing unit, an initial corner block arrangement array, an initial corner block direction array, an initial edge block arrangement array, and an initial edge block direction array, analyzing the output level signals, updating the initial corner block arrangement array, the initial corner block direction array, the initial edge block arrangement array, and the initial edge block direction array based on an analysis result, and generating Rubik's cube state data.
